(19) United States
(12) Patent Application Publication
(10) Pub. No.: US 2022/0201115 A1
(43) Pub. Date: Jun. 23, 2022

(54) SELF-CUSTOMIZABLE MICROLED ACCESSORY

(71) Applicants: Seong Kyu LIM, Daegu (KR); Myeong Hee KIM, Daegu (KR); Jong Ho LIM, Daegu (KR); Jong Yoon LIM, Daegu (KR)

(72) Inventors: Seong Kyu LIM, Daegu (KR); Myeong Hee KIM, Daegu (KR); Jong Ho LIM, Daegu (KR); Jong Yoon LIM, Daegu (KR)

(21) Appl. No.: 17/603,052

(22) PCT Filed: Apr. 10, 2020
(86) PCT No.: PCT/KR2020/004865

§ 371 Date: Oct. 12, 2021

(30) Foreign Application Priority Data
Apr. 12, 2019 (KR) 10-2019-0043068

(51) Int. Cl. H04M 1/72412; H04M 1/72409; G09G 3/32; G09G 3/00; A44C 15/00

(52) U.S. Cl. CPC H04M 1/72412; H04M 1/724095; H04M 1/724097; G09G 2360/144; G09G 3/035; A44C 15/0015; G09G 3/32

(57) ABSTRACT

The present invention relates to a self-customizable microLED accessory and, more specifically, to a useful invention comprising: an illuminatable accessory (100) to be worn on a specific body part of wearers in order to highlight the corresponding part; a driving means (200); a transparent microLED display skin (300) coated on the surface of the accessory (100); a master part (400) and a remote slave (500) provided in the accessory (100); and a smart phone (600), wherein the wearers use an application of the smart phone (600) so as to selectively control the transparent microLED display skin (300), thereby enabling continuous changing and expressing of various colors and patterns according to the current circumstances of the wearers.

### TECHNICAL FIELD

The present invention relates to a self-customizable microLED accessory, and more specifically, to a technique that allows a wearer to easily, continuously and selectively change the color and pattern of a transparent microLED display skin in various ways at will while wearing the accessary by coating the transparent microLED display skin on the outer surface of the accessary worn on any one among the wrists, ankles, fingers, neck, head, hair band, shoes, artificial nails, and artificial toenails of a person, configuring a master unit and a remote slave that control the transparent microLED display skin, and connecting a smartphone for the wearer to remotely control the transparent microLED display skin.

### BACKGROUND ART

Generally, accessories are used to decorate a body, and include rings, earrings, ornaments, necklaces, bracelets, hairpins, hair bands, brooches, tie pins, hats, bags, shoes, artificial nails, artificial toenails, and the like.

These accessories are originated by attaching natural objects such as seashells, leaves or the like on the body before the time when humans make and wear clothes, and seeing old animal murals or the like, it appears that undressed women wear a hat, a long necklace, a bracelet and the like, and various parts of the body such as the head, waist, elbow, ears, nose, lips, neck, chest, belly, arms, calves, legs, and feet are decorated with accessories since humans have an instinctive desire to decorate and express themselves.

On the other hand, the accessories are intended to induce a differentiated style by showing beauty or highlighting individuality at a corresponding position, and wearers prefer elegant or unique designs when the wearers wear the accessories in accordance with this purpose, and accordingly, people have a desire to purchase various accessories.

However, since there is a problem in that the conventional accessories are highlighted only in the daytime or where there is light and thus may not function as an accessory in a dark place or at night, in recent years, the accessories are made to emit light from the inside or outside so that they may function as an accessory in a dark place or at night.

First, conventional techniques are described below.

Korean Patent Registration No. 20-0251359 discloses a technique related to an accessory having a light-emitting function, which is configured to include a sensing unit configured at a predetermined location on the front side of the accessory to detect approach of a person from the outside and output a sensing signal; a control unit configured to be inserted in the accessory to receive the signal output from the sensing unit, process the signal to calculate an approaching distance of the person, and output a light emitting signal to emit light when the person approaches within a predetermined distance; and a light emitting unit installed at a predetermined location on the front side of the accessory to emit light in response to the light emitting signal received from the control unit.

Korean Patent Publication No. 10-2009-0120871 discloses a technique related to a light emitting accessory having an LED lighting decoration, the accessory comprising: a model unit processed in a predetermined color and formed in various shapes according to the characteristics of outer appearance design, and configured to emit internal light to the outside; a diffusion unit formed under the model unit to diffuse light; a light emitting unit for emitting light by configuring a light emitting device on a metal plate under the diffusion unit using an LED as a light source; a battery inserted under the light emitting unit to function as a power source; a battery case coupled to the model unit to support the battery from the bottom; and a fixing unit attached on the bottom of the battery case.

Korean Patent Publication No. 10-2009-0102005 discloses a technique related to a light emitting necklace having an LED lighting decoration, the necklace comprising: a model body processed in a predetermined color and formed in various shapes according to the characteristics of outer appearance design, configured in a structure having a middle portion divided into upper and lower parts combined to be opened and closed seeing from the lateral side, having an empty inner space for diffusing light from the inside when light is emitted, and configured to emit internal light to the outside; a light emitting body for emitting light by configuring a light emitting device using an LED as a light source at the inner center of the model body; a wire electrically connected to both sides of the light emitting body to flow electricity, coming out of the model body through a wire hole configured in the model body, and having the same length on both sides; a battery case configured to be connected to an end of the wire opposite to the model body and the light emitting body; and a battery inserted in the battery case to supply power.

However, although the conventional techniques described above may induce wearer's interest while functioning as an accessory in a dark place or at night by emitting light to the outside of the accessory, as the light is emitted only in a single color, the design or the like is very monotonous.

That is, the conventional accessories have a problem in that there is no choice but to wear the accessories only in the fixed state and in the color of the accessories provided by those who manufactured the accessories.

### DISCLOSURE OF INVENTION

### Technical Problem

Therefore, the present invention has been made in view of the above problems, and it is an object of the present invention to provide a self-customizable microLED accessory comprising: one or more transparent microLED display skins configured to be fully or partly coated on the outer surface of the accessory; a master unit and a remote slave configured at one side on the outer surface of the accessory at a position close to the transparent microLED display skin to control the transparent microLED display skin; and one or more smartphones connected to remotely control the master unit and the remote slave, wherein the transparent microLED display skin is controlled by using an APP embedded in the smartphone so that the wearer himself or herself may become a creator of the accessory by expressing a single color or multiple colors and various patterns to be diversely and continuously changed according to the external environment or mood.

### Technical Solution

To accomplish the above object, according to one aspect of the present invention, there is provided a self-customizable microLED accessory 100 worn on any one or more among a person's wrist, ankle, finger, neck, head, eyelash, artificial nail, and artificial toenail, the accessory comprising: a transparent microLED display skin 300 configured outside the body of the accessory 100 to include a transparent flexible substrate 310 having transparency and flexibility, and a semiconductor device layer 320 having microLED pixels 330 transferred and attached on the transparent flexible substrate 310, and coated on the surface of the accessory 100; a master unit 400 configured outside the body of the accessory 100 to be spaced apart from the transparent microLED display skin 300, and provided with a power switch 410 for controlling a power supply unit 430, a charging port 420 for charging a battery through a USB cable, the power supply unit 430 controlled by the power switch 410, the battery 440 for storing power charged through the charging port 420, a wireless power supply unit 450 having a wireless electric coil to wirelessly supply power to the power supply unit 430, a short-range wireless communication unit 460 for performing short-range wireless communication with external devices and other devices including a smartphone 600, a main control unit 470 for controlling color expression in the transparent microLED display skin 300 of the accessory, an energy harvesting unit 480 for self-generation of energy, and a photodetector 490 for detecting brightness of light outside the accessory; a remote slave 500 configured at a position spaced apart from the master unit 400 of the body of the accessory 100 by a predetermined distance, and provided with a wireless electric antenna 510 for receiving power generated by the wireless power supply unit 450, a remote control unit 520 for driving and controlling the transparent microLED display skin 300, a transceiver unit 530 for performing close proximity remote transmission and reception with the master unit 400, an energy harvesting unit 540 for self-generation of energy, and a photodetector 550 for detecting brightness of light outside the accessory; and a smartphone 600 including an APP capable of controlling the main control unit 470 or the remote control unit 520 of the master unit 400 or the remote slave 500 through a short-range wireless communication method with the master unit the short-range wireless communication unit 460 of the master unit 400

The photodetectors 490 and 550 detect an amount of external light applied to the accessory, and then apply them to the main control unit 470 and the remote control unit 520, and the main control unit 470 and the remote control unit 520 control display luminance brightness of the transparent microLED display skin 300 based on the received amount of light.

The energy harvesting units 480 and 540 are configured of any one or a combination of a photoelectric element, a thermoelectric element, a piezoelectric element, and a wireless electric conversion element.

When a specific transparent microLED display skin 300 is controlled through the APP, the transparent microLED display skin 300 is controlled by the master unit 400 or the remote slave 500 close to the specific transparent microLED display skin 300.

### Advantageous Effects

According to the self-customizable microLED accessory of the present invention, as the purpose of the accessory may be maintained as is even in a dark place or at night, and at the same time, various colors and patterns may be easily and continuously changed in accordance with the current situation of a user, such as a ceremony, a festival, a party, an event or the like, this is an innovative invention that can immediately respond to a field situation (the wearer expresses himself or herself as a creator), and enhance the fun of users and lead the future fashion of accessories through various changes in colors and patterns, and this is a useful invention having an effect of using the accessory for a long time owing to low power consumption, rechargeable battery, and autonomous power supply.

### BRIEF DESCRIPTION OF THE DRAWINGS

FIG. 1 is a front view showing a preferred embodiment of the present invention.

FIG. 2 is a cross-sectional view showing a preferred embodiment of the present invention.

FIG. 3 is a view showing a transparent microLED display skin of the present invention.

FIG. 4 is a block diagram showing a preferred embodiment of a master unit of the present invention.

FIG. 5 is a block diagram showing a preferred embodiment of a remote slave of the present invention.

FIG. 6 is a view showing that it is operated in a short-range wireless communication method between a smartphone and accessories of the present invention.

FIG. 7 is a view showing another embodiment of the present invention.

FIG. 8 is a view showing another embodiment of the present invention.

FIG. 9 is a view showing another embodiment of the present invention.

### DESCRIPTION OF SYMBOLS

50: body part

100: accessories

100a: necklace

110b: ring

200: driving means

210: rotating assembly

220: driving motor

300: transparent microLED display skin

310: transparent flexible substrate

320: semiconductor device layer

330: microLED pixel

331: positive electrode layer

332: transparent conductive layer

333: transparent p-electrode layer

334: p-GaN layer

335: active layer

336: n-GaN layer

337: transparent n-electrode layer

338: transparent insulating layer

400: master unit

410: power switch

420: charging port

430: power supply unit

440: battery

450: wireless power supply unit

460: short-range wireless communication unit

470: main control unit

480: energy harvesting unit

490: photodetector

500: remote slave

510: wireless electric antenna

520: remote control unit 530: transceiver unit

540: energy harvesting unit

550: photodetector

600: smartphone

### BEST MODE FOR CARRYING OUT THE INVENTION

The present invention provides a self-customizable microLED accessory that allows a wearer to selectively and continuously change the color and pattern of a transparent microLED display skin in various ways by coating the transparent microLED display skin on the outer surface of the accessary worn on any one or more among the wrists, ankles, fingers, neck, head, eyelashes, artificial nails, and artificial toenails of a person, configuring a master unit and a remote slave that control the transparent microLED display skin, and connecting a smartphone for the wearer to remotely control the transparent microLED display skin.

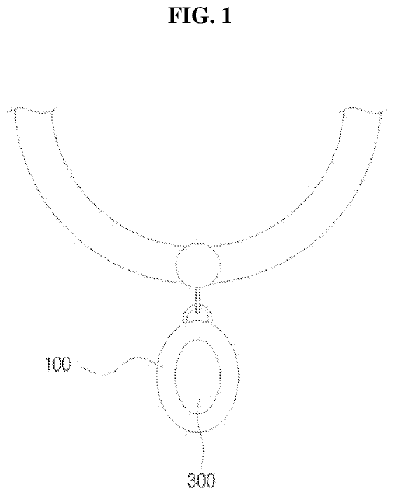

Hereinafter, a preferred embodiment of the present invention for achieving the above objects in relation to the accompanying drawings will be described with reference to FIGS. 1 to 9.

First, the present invention is configured to include an accessory 100, a transparent microLED display skin 300, a master unit 400, a remote slave 500, and a smartphone 600.

Here, the accessory refers to a ring, a necklace, an ankle bracelet, a bracelet, an earring, a hair band, an artificial nail, an artificial toenail, or the like, and as an embodiment of the present invention, the necklace among the accessories will be described as an example.

In the case of the necklace (accessory), generally, a latching unit that can be hung on the wearer's neck is configured, and a necklace body that can highlight the beauty of a corresponding location is configured on one side of the latching unit.

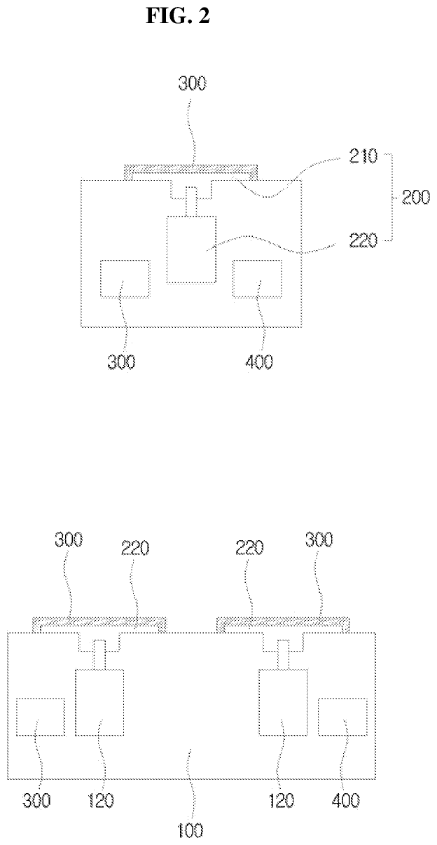

Here, a driving means 200 is configured in the accessory as shown in FIG. 2, and the driving means 200 is configured on the outer surface of the body of the accessory 100 and configured of a rotating assembly 210 inserted inside the accessory 100 on the bottom, and a driving motor 220 having a rotating shaft connected to the bottom of the rotating assembly 210 inside the accessory 100, and the rotating assembly 210 may rotate according to the operation of the driving motor 220.

At this point, it is preferable to additionally configure a battery for driving the driving motor 220 in the driving means 200.

As the rotating assembly 210 may rotate while emitting a color when the transparent microLED display skin 300, the master unit 400, the remote slave 500, and the smartphone 600 are configured and used as described below, there is an effect of enhancing the fun in using the accessory.

In addition, one or more rotating assemblies 210 may be configured as shown in FIG. 2, and when one or more rotating assemblies 210 are configured, the rotating assemblies 210 may operate by configuring the driving motor 220 for each rotating assembly 210 or by configuring one driving motor 220 for all the rotating assemblies 210, and in the present invention, it is shown that the driving motor 220 is configured to operate one rotating assembly 210.

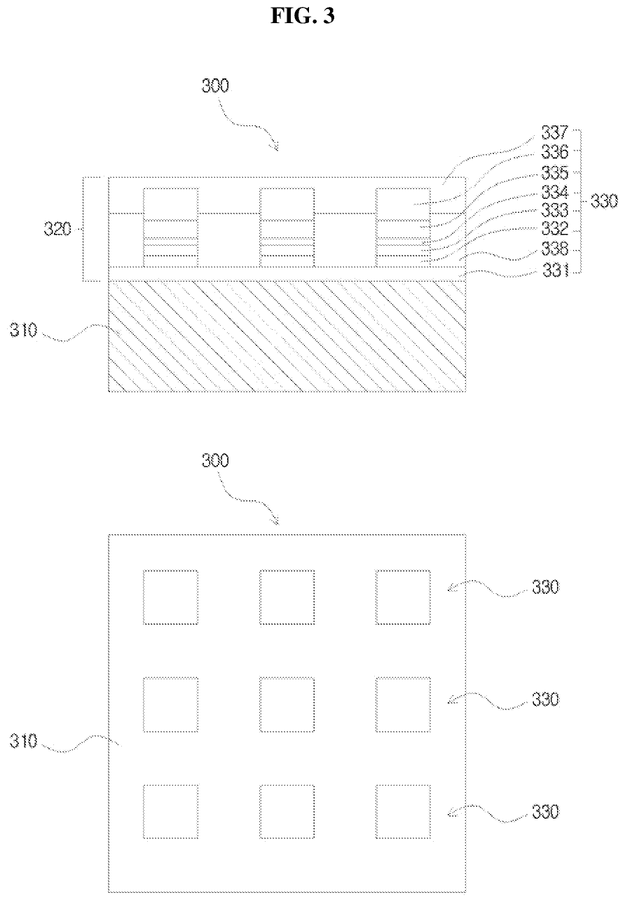

Meanwhile, as shown in FIG. 3, the transparent microLED display skin 300 is configured of a transparent flexible substrate 310 having transparency and flexibility, and a semiconductor device layer 320 having microLED pixels 330 transferred and attached on the transparent flexible substrate 310, and is coated on the outer surface of the accessory 100, preferably, on the surface of the rotating assembly 210.

At this point, the transparent microLED display skin 300 may be fully or partly coated on the outer surface of a necklace (accessory). When the transparent microLED display skins 300 are partly coated, it is configured to be spaced apart from each other at regular intervals, and different colors may be expressed on the transparent microLED display skins 300.

The microLED display is a display in which microLED particles with a size of 5 to 100 μm (1/100,000 Cm) are connected one after another on a substrate (a transparent substrate in the present invention), and it is suitable for implementing a flexible or rollable screen by using an LED chip itself as a pixel, may be used for a long time as power consumption is very small compared to an OLED, and is much excellent from the aspect of illuminance, saturation, and power efficiency compared to existing OLEDs.

The transparent microLED display skin 300 as described above is attached to be coated on the surface of the rotating assembly 210, and the transparent microLED display skin 300 uses a transparent flexible substrate 310 having both transparency and flexibility to function as an accessory as is even when the microLED display does not work, and the pixels made of microLED chips, i.e., the microLED pixels 330, are also configured to maximize the transparency.

On the other hand, the transparent microLED display skin 300 of the present invention is configured by implanting a semiconductor device layer 320 having numerous microLED pixels 330 made of micro p-n diode layer on the transparent flexible substrate 310 in a micro transfer printing technique, and at this point, in performing the transfer printing technique, it is preferable to transfer and attach 10,000 or more microLED pixels 330 per second on the transparent flexible substrate 310 using a roll transfer technique.

The microLED pixels 330 are prepared on a native substrate and then transferred and printed on the transparent flexible substrate 310, and the native substrate and unnecessary portions are then removed thereafter.

The transparent flexible substrate 310 has transparency and flexibility and is selected in a thickness range among 5 to 10 μm, 10 to 50 μm, 50 to 100 μm, 100 to 200 μm, 200 to 500 μm, 0.5 to 1 mm, 1 to 5 mm, and 5 to 10 mm.

As shown in FIG. 3, the transparent microLED display skin 300 is a configuration in which the semiconductor device layer 320 having microLED pixels 330 is formed to be attached on the transparent flexible substrate 310 having both transparency and flexibility.

The microLED pixel 330 of the semiconductor device layer 320 is configured of a positive electrode layer 331, a transparent conductive layer 332, a transparent p-electrode layer 333, a p-GaN layer 334, an active layer 335, an n-GaN layer 336, and an upper transparent n-electrode layer 337, and a transparent insulating layer 338 is formed between the microLED pixels 330. Each of the microLED pixels 330 formed in the semiconductor device layer 320 is a p-n diode layer, which is configured of a compound semiconductor having a band gap corresponding to a specific region in the spectrum, and for example, it is formed of gallium nitride (GaN), which is a III to V nitride material.

The transparent p-electrode layer 338 is a layer for supplying power, and forms an electrode with an oxide containing Al, Ga, Ag, Sn, In, Zn, Co, Ni, or Au having a transmittance of 70% or more. The positive electrode layer 331 becomes a circuit pattern, a bump, or a conductive adhesive layer, and the transparent n-electrode layer 337 has electrical conductivity. The positive electrode layer 331 may be selected from a group of silver and nickel having reflectivity to the visible spectrum, and forms a latent reflective mirror layer.

In addition, the present invention may implement the microLED display skin 300 in full color by arranging three elements, i.e., microLED panels, having red (R), green (G) and blue (B) colors.

In other words, in the present invention, when the transparent microLED display skin 300 of the accessory 100 does not operate, the color and design of a general accessory are expressed, and when the transparent microLED display skin 300 operates, diverse colors may be output to the outside.

Here, when a specific transparent microLED display skin 300 is controlled through the APP, the transparent microLED display skin 300 is controlled by the master unit 400 or the remote slave 500 close to the specific transparent microLED display skin 300.

In addition, the transparent microLED display skin 300 is configured to be fully or partly coated on the outer surface of the accessory 100, and may express various colors and patterns toward the outside of the accessory 100 under the control of the smartphone 600 described below.

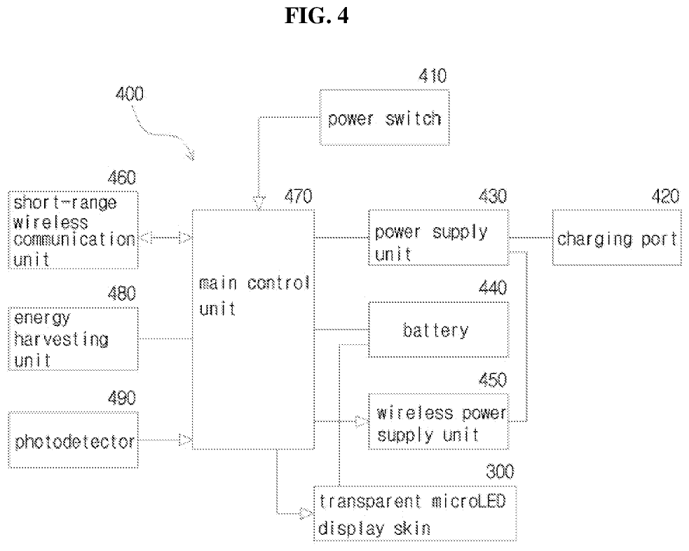

Meanwhile, the master unit 400 is configured outside or inside the accessory 100 as shown in FIG. 4, and is configured of a power switch 410 for controlling a power supply unit 430, a charging port 420 for charging a battery through a USB cable, the power supply unit 430 controlled by the power switch 410, the battery 440 for storing power charged through the charging port 420, a wireless power supply unit 450 having a wireless electric coil to wirelessly supply power to the power supply unit 430, a short-range wireless communication unit 460 for performing short-range wireless communication with external devices and other devices including a smartphone 600, a main control unit 470 for controlling color expression in the transparent microLED display skin 300, an energy harvesting unit 480 for self-generation of energy, and a photodetector 490 for detecting brightness of light outside the accessory.

It is preferable that the IC chip of the main control unit 470 embedded in the accessory 100 is implemented as an application specific integrated circuit (ASIC), and wireless electricity and the energy harvesting unit 480 is able to supply energy by applying a solar cell (photovoltaic cell).

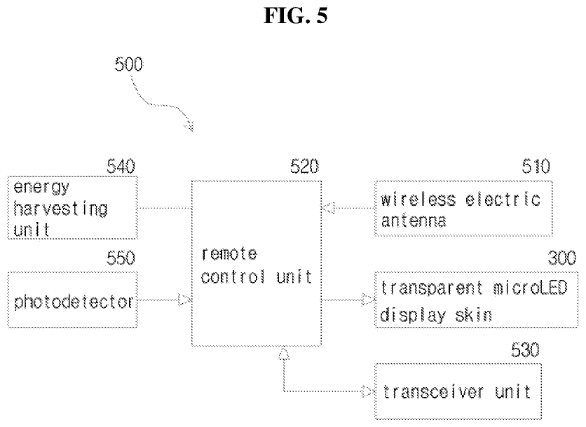

On the other hand, as shown in FIG. 5, the remote slave 500 for wirelessly receiving power supplied from the master unit 400 configured in the accessory 100 is configured at a position spaced apart from the master unit 400 of the accessory 100 by a predetermined distance, and includes a wireless electric antenna 510 for receiving power generated by the wireless power supply unit 450, a remote control unit 520 formed in an IC chip for driving and controlling the transparent microLED display skin 300, a transceiver unit 530 for performing close proximity remote transmission and reception with the master unit 400, an energy harvesting unit 540 for self-generation of energy, and a photodetector 550 for detecting the brightness of light outside the accessory).

The integrated circuit (IC) of the remote control unit 520 may configure a micron-scale integrated circuit using a complementary-metal-oxide semiconductor (CMOS), and the area of the IC chip is 1 mm×1 mm, and the thickness is preferably 0.5 mm.

Meanwhile, power generated through the resonance phenomenon in the wireless electric coil of the wireless power supply unit 450 configured in the accessory 100 of the present invention is received by the wireless electric antenna 510 of the remote slave 500, and the power received under the control of the remote controller 520 is used to drive the transparent microLED display skin 300.

Here, the energy harvesting units 480 and 540 are means for harvesting energy in the surroundings and may generate power without receiving power from a separate battery and supply the power to each part inside, and are preferably configured of any one or a combination of a photoelectric element, a thermoelectric element, a piezoelectric element, and a wireless electric conversion element. The photodetectors 490 and 550 detect the amount of external light applied to the accessory, and then apply them to the main control unit 470 and the remote control unit 520, and the main control unit 470 and the remote control unit 520 may control the display luminance brightness of the transparent microLED display skin 300 based on the received amount of light.

In addition, it is shown in the present invention that the master unit 400 is configured inside the accessory 100.

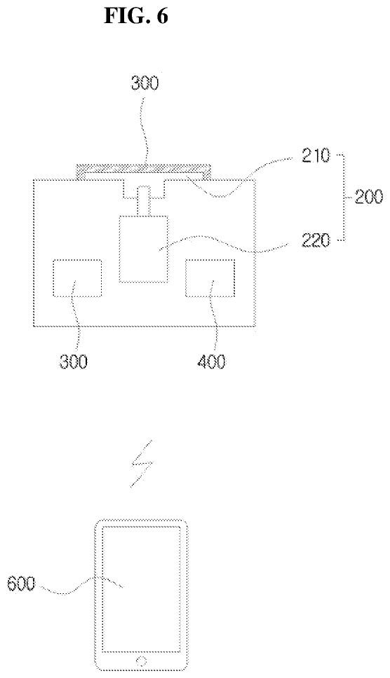

In addition, as shown in FIG. 6, a smartphone 600 is further provided to include an APP capable of controlling the main control unit 470 or the remote control unit 520 of the master unit 400 or the remote slave 500 through a short-range wireless communication method with the short-range wireless communication unit 460 of the master unit 400.

The wireless transmission and reception method between the master unit 400 and the smartphone 600 may use a Li-Fi technology that implements a fast communication speed using the wavelength of light emitted from an LED, and particularly, when the microLED technique of the present invention is applied, the effect of miniaturizing and light-weighting the parts is increased.

That is, through the smartphone 600 of the present invention, as shown in FIG. 6, change of design and color may be controlled through short-range remote control between the accessory 100 and the smartphone 600. The master unit 400 may wirelessly connect to the smartphone 600 using a short-range wireless communication method such as Bluetooth communication, Wi-Fi communication, NFC communication, IR communication, or Li-Fi communication. When users selectively control the APP included in the smartphone 600, various colors and patterns may be expressed on the transparent microLED display skin 300 according to a control command.

In addition, in operating the transparent microLED display skin 300 using the APP of the smartphone 600 that controls the master unit 400 and the remote slave 500 of the present invention, when a control command is initially transmitted to the master unit 400, the master unit 400 operates the transparent microLED display skin 300, and when the distance between the master unit 400 and a specific transparent microLED display skin 300 is long, the master unit 400 transmits the control command to the remote slave 500, and the remote slave 500 operates the corresponding transparent microLED display skin 300.

That is, when a specific transparent microLED display skin 300 is initially operated using the smartphone 600, the master unit 400 or the remote slave 500 close to the specific transparent microLED display skin 300 in distance operates the specific transparent microLED display skin 300, and thus there is an advantage of quickly and accurately controlling the transparent microLED display skin 300.

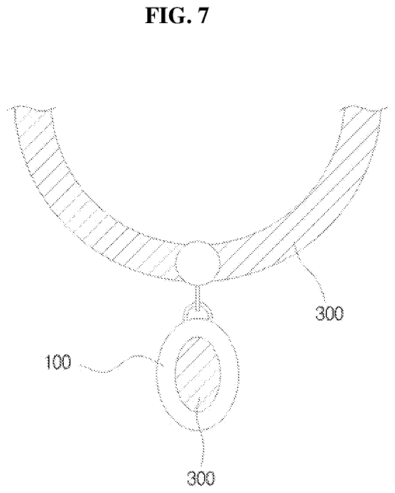

In addition, although it is described in the present invention that the transparent microLED display skin 300 is coated only on the outer surface of the rotating assembly 210 overall, the transparent microLED display skin 300 may be configured to be coated on the outer surface of the latching unit of the necklace (the part that fixes the necklace after the necklace is hung on the wearer's neck) in addition to the outer surface of the rotating assembly 210, and the master unit 400 may be configured inside or outside the accessory 100 and the remote slave 500 is configured at one end of the inside or outside of the latching unit of the necklace so that the master unit 400 controls the transparent microLED display skin 300 coated on the outer surface of the rotating assembly 210, and the remote slave 500 may be configured to control the transparent microLED display skin 300 coated on the outer surface of the latching unit (the master unit 400 and the remote slave 500 are not shown in FIG. 7).

The reason why it can be configured as described above is that as described above, since the master unit 400, the remote slave 500, and the smartphone 600 may transmit and receive signals through a short-range wireless communication method, when the user initially sets using the APP of the smartphone 600 to control any one transparent microLED display skin 300, the master unit 400 receiving a corresponding signal controls the transparent microLED display skin 300 that the master unit 400 itself should control, and when there is a transparent microLED display skin 300 that should be controlled by the remote slave 500, the master unit 400 transmits the signal to the remote slave 500, and the remote slave 500 finally controls a corresponding transparent microLED display skin 300.

As described above, the self-customizable microLED accessory of the present invention has been described using a necklace as an example among a number of accessories, and in the case of an artificial nail or artificial toenail, a different color pattern may be expressed for each nail or toenail. The same configuration may be applied to all the other accessories, and it is not limited by the embodiments of the present invention.

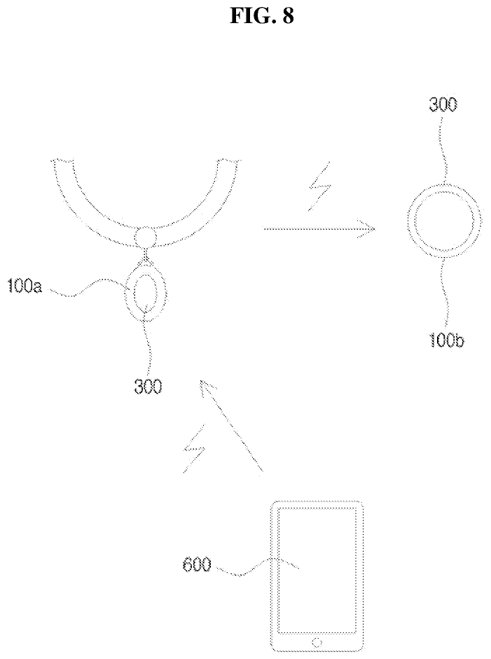

Meanwhile, the accessory 100 is configured as a necklace 100a or a ring 100b as shown in FIG. 8, and after configuring the transparent microLED display skin 300 to be coated on the outer surface of the necklace 100a and configuring the transparent microLED display skin 300 to be coated on the outer surface of the ring 100b, the master unit 400 is configured inside the necklace 100a and the remote slave 500 is configured inside the ring 100b so that the master unit 400 may control the transparent microLED display skin 300 of the necklace 100a, and the remote slave 500 may control the transparent microLED display skin 300 of the ring 100b according to a signal transferred from the smartphone 600.

At this point, the remote slave 500 does not receive the signal directly from the smartphone 600 and receives the signal from the master unit 400, and the master unit 400 and the remote slave 500 are not shown separately.

That is, the present invention may configure a plurality of transparent microLED display skins 300 in one accessory 100 and then configure the master unit 400 and the remote slave 500 so that the transparent microLED display skins 300 may be controlled by the master unit 400 or the remote slave 500 located in a short distance, or a transparent microLED display skin 300 may be configured in each of a plurality of accessories so that the master unit 400 may be configured to be used for one accessory and the remote slave 500 may be configured to be used for another accessory 100.

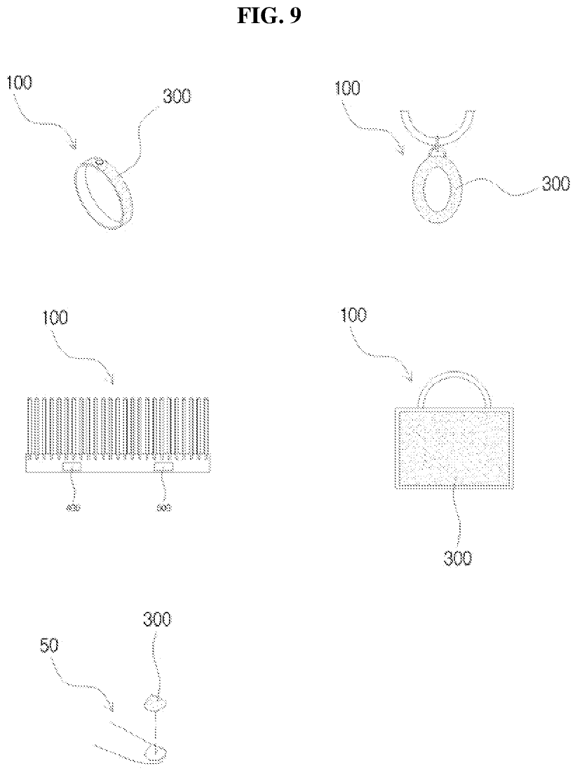

In addition, as shown in FIG. 9, the present invention shows, for example, an accessory, a ring, a necklace, a wig, an artificial fingernail, an artificial toenail, or the like as an accessory, and a finger of a person is shown as a part 50 of the body, and an eyelash or the like may be a part of the body, and shoes that a person puts on his or her feet may be further added as an accessory.

According to a self-customizable microLED accessory of the present invention, as the purpose of the accessory may be maintained as is even in a dark place or at night, and at the same time, various colors and patterns may be easily changed in accordance with the current situation of a user, such as a ceremony, a festival, a party, an event or the like, this is an innovative invention that can immediately respond to a field situation (the wearer expresses himself or herself as a creator), and enhance the fun of users and lead the future fashion of accessories through various changes in colors and patterns, and this is a useful invention having an effect of using the accessory for a long time owing to low power consumption, rechargeable battery, and autonomous power supply.

1. A self-customizable microLED accessory 100 worn on any one among a person's wrist, ankle, finger, neck, head, eyelash, artificial nail, and artificial toenail, the accessory comprising:
a transparent microLED display skin 300 configured outside the accessory 100 to include a transparent flexible substrate 310 having transparency and flexibility, and a semiconductor device layer 320 having microLED pixels 330 transferred and attached on the transparent flexible substrate 310, and coated on the surface of the accessory 100;
a master unit 400 configured outside a body of the accessory 100 to be spaced apart from the transparent microLED display skin 300, and provided with a power switch 410 for controlling a power supply unit 430, a charging port 420 for charging a battery through a USB cable, the power supply unit 430 controlled by the power switch 410, the battery 440 for storing power charged through the charging port 420, a wireless power supply unit 450 having a wireless electric coil to wirelessly supply power to the power supply unit 430, a short-range wireless communication unit 460 for performing short-range wireless communication with external devices and other devices including a smartphone 600, a main control unit 470 for controlling color expression in the transparent microLED display skin 300 of the accessory 100, an energy harvesting unit 480 for self-generation of energy, and a photodetector 490 for detecting brightness of light outside the accessory;
a remote slave 500 configured at a position spaced apart from the master unit 400 of the body of the accessory 100 by a predetermined distance, and provided with a wireless electric antenna 510 for receiving power generated by the wireless power supply unit 450, a remote control unit 520 for driving and controlling the transparent microLED display skin 300, a transceiver unit 530 for performing close proximity remote transmission and reception with the master unit 400, an energy harvesting unit 540 for self-generation of energy, and a photodetector 550 for detecting brightness of light outside the accessory; and
a smartphone 600 including an APP capable of controlling the main control unit 470 or the remote control unit 520 of the master unit 400 or the remote slave 500 through a short-range wireless communication method with the short-range wireless communication unit 460 of the master unit 400.

2. The accessory according to claim 1, wherein the photodetectors 490 and 550 detect an amount of external light applied to the accessory 100, and then apply them to the main control unit 470 and the remote control unit 520, and the main control unit 470 and the remote control unit 520 control display luminance brightness of the transparent microLED display skin 300 based on the received amount of light.

3. The accessory according to claim 1, wherein the energy harvesting units 480 and 540 are configured of any one or a combination of a photoelectric element, a thermoelectric element, a piezoelectric element, and a wireless electric conversion element.

4. The accessory according to claim 1, wherein when a specific transparent microLED display skin 300 is controlled through the APP, the transparent microLED display skin 300 is controlled by the master unit 400 or the remote slave 500 close to the specific transparent microLED display skin 300.
